(19) United States
(12) Patent Application Publication
(10) Pub. No.: US 2026/0223340 A1
(43) Pub. Date: Jul. 30, 2026

(54) ELECTRONIC EQUIPMENT WITH AN ELECTROMAGNETIC SHIELD SYSTEM

(71) Applicant: THALES NEDERLAND B.V., HENGELO (NL)

(72) Inventors: Wessel Willems WITS, HENGELO (NL); Benno Gerhardus Johannes GEERDINK, HENGELO (NL); Jacob Corstiaan HAGE, HENGELO (NL)

(21) Appl. No.: 19/142,008

(22) PCT Filed: Dec. 22, 2023
(86) PCT No.: PCT/EP2023/087770

§ 371 Date: Jun. 20, 2025

(30) Foreign Application Priority Data
Dec. 27, 2022 (NL) 2033842

(51) Int. Cl. H05K 9/00; G01S 7/02; H01Q 1/52; H01Q 3/04

(52) U.S. Cl. CPC H05K 9/0015; G01S 7/027; H01Q 1/526; H01Q 3/04; H05K 9/009

(57) ABSTRACT

An electronic equipment with an electromagnetic shield system includes: a first assembly and a second assembly, the first assembly and the second assembly being connected in such a manner that there is no direct transfer of forces between them in an operational configuration of the electronic equipment via the electromagnetic shield system; the electromagnetic shield system including: a flexible seal configured for providing an electromagnetic shield between the first and second assemblies, at least one rigid bridge for rigidly holding together the flexible seal and at least one among the first assembly and the second assembly, or for rigidly holding the flexible seal, so as to intervene on the electronic equipment in a maintenance configuration of the electronic equipment.

### TECHNICAL FIELD

The invention relates to an electronic equipment with an electromagnetic shield system.

The requirements for EMC/EMI (Electromagnetic Compatibility/Electromagnetic Interference) shielding are getting more and more strict, in particular for situations in which sensitive information is present, such as in radar systems. Even the tiniest leakage of information (eavesdropping) and vice versa potential susceptibility to external interference or jamming sources have to be prevented.

FIG. 1 illustrates an exemplary rotating radar of the prior art. The rotating radar comprises an antenna system for transmitting and receiving radio waves to the outside world, for example for measuring the distance to a target, the velocity of a target based on the reflection of radio waves, or for interrogating the transponder of an aircraft.

The rotating radar also comprises a stationary part, including, for example, a processing unit for computing the waveform and for processing the received signals, and also means for attaching the radar to the ground or the deck of a ship, for example via support legs or a support cone.

The rotating radar also comprises a rotating joint, which provides the critical interface between the rotating antenna system and the stationary part of the radar. The rotating joint is made of a rotating part, which is connected to the antenna system, and a static part, which is connected to the ground segment of the radar. The rotating part of the joint and the static part of the joint are coupled one to each other through a bearing.

The antenna system is also coupled to the support legs through a bearing. A motor rotatively drives the antenna system and the rotating part of the rotating joint.

FIG. 1 illustrates potential electromagnetic interference pathways of a rotating radar. Although the radar manufacturer can guarantee a high EMC/EMI protection within the radar, the interface between the radar and the outside world, such as at the support legs, is a weak area. Besides, a bearing in motion has less shielding effectiveness, due to thin film lubrication of the bearing balls and hence less electrical contact through the bearing.

It is known to use flexible seals, such as a conductive fabrics, in order to provide an EMC/EMI shield (as disclosed in U.S. Pat. No. 5,001,297 A, US 2009/114438 A1, U.S. Pat. No. 5,511,798 A, GB 2 184 294 A or KR 2008 0044988 A). However, the application of a flexible seal in a rotating radar would pose significant problems. Indeed, a rotating joint is a line replaceable unit due to its inherent wear attributes (mechanical stress). The rotating joint has to be easily dismounted, from the bottom, without dismounting the complete antenna system. If the flexible seal was attached to the antenna system and to the rotating joint, without any means to protect the flexible seal, dismounting the rotating joint would result in tearing the flexible seal, then the flexible seal has to be replaced by a new one, which implies a further task of qualification of the proper installation of the seal.

Also, reattaching a flexible seal after repair in a confined space in a quality-wise reliable manner is difficult. Hence, it leaves a risk of unknowingly exposing the radar system to EMC/EMI interference.

Therefore, there is a need for providing in an operational configuration, in particular without any mechanical interaction between system components via the electromagnetic shield in an operational configuration, and with the ability to have the system components easily disassembled and reassembled without jeopardizing the quality of the shield.

An object of the present invention is an electronic equipment as defined in claims 1 to 19.

Another object of the present invention is a method for replacing or performing maintenance on the electronic equipment as defined in claims 20 to 23.

Another object of the present invention is an electromagnetic shield system as defined in claims 24 to 37.

### DESCRIPTION OF THE FIGURES

Additional features and advantages of the present invention will become apparent from the subsequent description, taken in conjunction with the accompanying drawings:

FIG. 1 illustrates the pathways of potential disturbances and leakage paths in a rotating radar, due to the necessity of installing a rotating system on a fixed platform.

FIGS. 2 and 3 illustrate an embodiment of the electronic equipment according to the invention, without the first and second support, respectively in operational and maintenance configurations.

FIGS. 4, 5 and 6 illustrate an embodiment of the electronic equipment according to the invention, comprising the first and second support.

FIGS. 7 and 8 illustrate perspective views of the electronic equipment according to the invention, in a rotatable radar system.

FIGS. 9 to 12 illustrate different perspective views of the electronic equipment according to the invention, in a mast configuration.

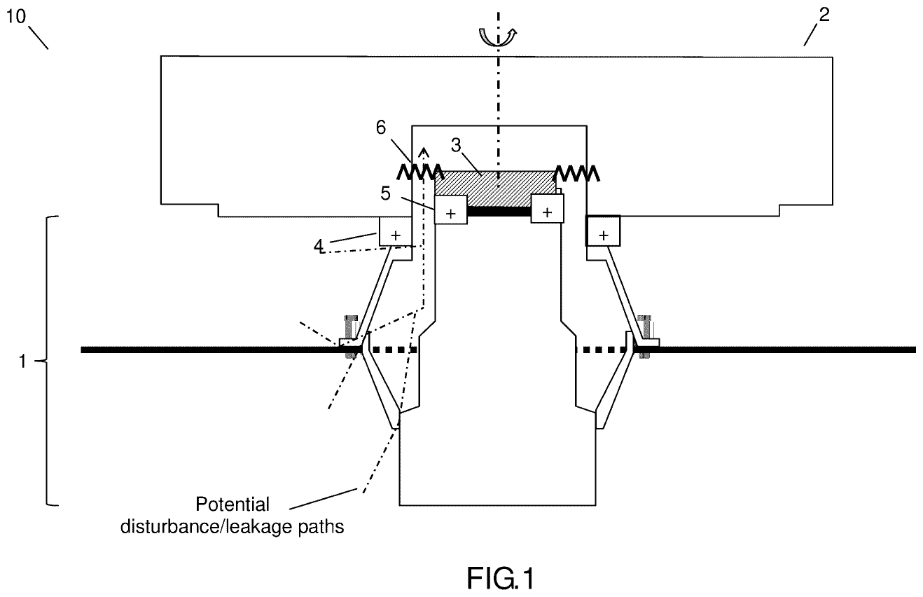

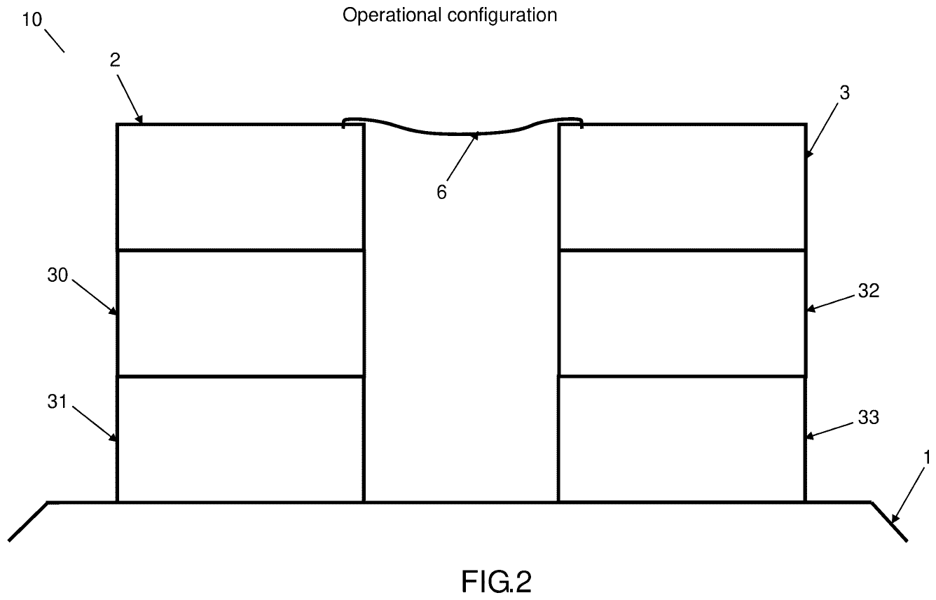

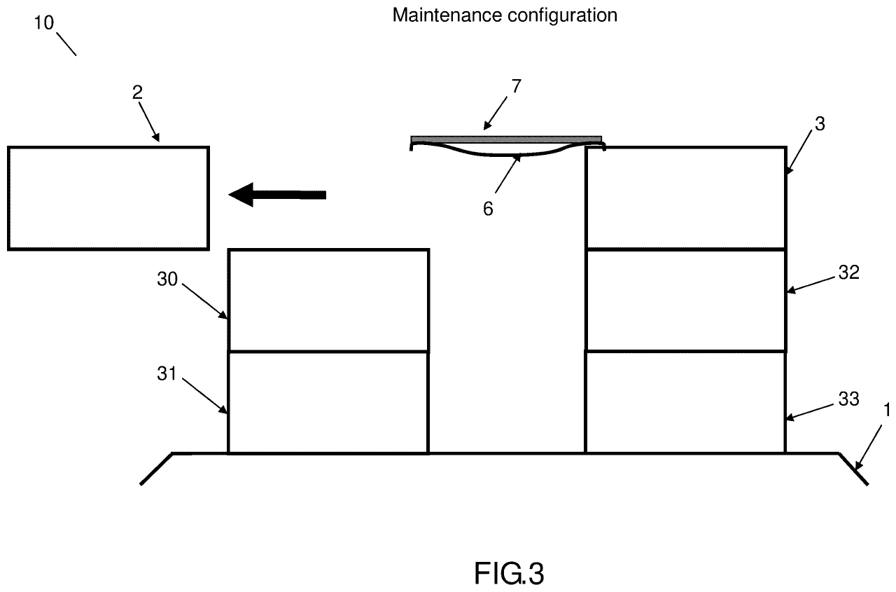

A first embodiment of the invention is illustrated in FIGS. 2 and 3. The first assembly 2 and the second assembly 3, which are spaced apart one to the other, are parts of an electronic equipment 10. A flexible seal 6 of an electromagnetic shield system is located between the first assembly 2 and the second assembly 3, and provides an electromagnetic shield. Therefore, electromagnetic emissions are contained in the enclosed space which is defined by the first 2 and second assembly 3. At the same time, components which are located in the enclosed space are not vulnerable to electromagnetic radiation (e.g. an attack) from the external environment. In accordance with the invention, there is no direct transfer of forces between the first assembly 2 and the second assembly 3 via the electromagnetic shield system in an operational configuration of the electronic equipment 10. In particular, there is no direct transfer of forces between the first assembly 2 and the second assembly 3 via the seal and/or a bridge 7 in an operational configuration of the electronic equipment 10. In a preferred embodiment, the flexible seal 6 is a conductive fabric, which has the advantage of having high attenuation properties with a light weight and reduced cost. The conductive fabric may be composed of several stacked layers.

The first assembly 2 and the second assembly 3 are directly or indirectly connected to a base 1. The base is a fixed support, which may be, for example, the deck of a ship. A direct connection implies that the first assembly 2 and the second assembly 3 lay on the base 1. An indirect connection implies that the first assembly 2 and/or the second assembly 3 rest on intermediate mechanical parts (30, 31, 32, 33). In the operational configuration, the flexible seal 6 provides a flexible connection between the first assembly 2 and the second assembly 3, so that a small relative movement of one of the assemblies is not transmitted to the other assembly. Also, any misalignment due to manufacturing conditions or installation may be corrected by the flexible connection.

For example, the second assembly 3 may be a part of a ship's mast structure, and the first assembly 2 may be an antenna or a part of an antenna located in the mast. The mast and the antenna are static, but in operational configuration, for example during a mission, there may be slight relative movements of the antenna with regards to the mast, mainly due to the movements of the ship and inertial effects.

In another example, the first assembly 2 is the antenna of a rotating radar, and the second assembly 3 is the rotating part of a rotating joint. In operational configuration, the antenna and the rotating part of the rotating joint rotate together, however there may not be any (unwanted) transfer of forces between the antenna and the rotating joint caused by the seal. Indeed, a drive system drives the antenna in rotation and a dedicated coupling system transfers the rotational movement from the antenna to the rotating joint (or inversely).

In the maintenance configuration, which is illustrated by FIG. 3, a rigid bridge 7 of the electromagnetic shield system rigidly holds together the flexible seal 6 and the second assembly 3. The rigid bridge 7 in particular holds the flexible seal 6 at a location of the flexible seal 6 that connects to the first assembly 2 in an operational configuration, i.e. at the location of the interface between the flexible seal 6 and the first assembly 2 in an operational configuration. This allows easy reinstallation and good alignment of the flexible seal 6 after maintenance of the first assembly has been completed, because the flexible 6 is kept in its shielding shape and/or position by the bridge 7, even when the first assembly 2 is temporarily removed or when it is temporarily disconnected from the first assembly 2. In other embodiments of the maintenance configuration, the rigid bridge 7 could also rigidly hold together the flexible seal 6 and the first assembly 2, or it could hold together the flexible seal 6 and both assemblies 2,3. The rigid bridge 7 is not limited to a particular material or shape, provided that it guarantees that no excessive force or movement may be exerted on the flexible seal while removing either the first assembly 2 or second assembly 3. The rigid bridge 7 is in particular arranged to hold the seal such that it spans the distance between the first assembly and the second assembly, said distance being the distance between the first assembly and second assembly in the operational configuration, i.e. the distance that is spanned by the flexible seal. For example, the rigid bridge 7 may be composed of aluminum.

At the beginning of the maintenance operation of the first assembly 2, the rigid bridge 7 is attached to the second assembly 3 and to the flexible seal 6, by using fastening means such as bolts. This enables a removal of the first assembly 2. Since the rigid bridge 7 is still attached to the flexible seal 6 and to the second assembly 3, the flexible seal 6 is not torn, even during the manipulation of the first assembly 2.

The steps of a method for replacing or performing maintenance on the electronic equipment are resumed as follows:

In a first step S1), the flexible seal 6 and at least one among the first assembly 2 and the second assembly 3 are rigidly held together, via the bridge 7.

Thus, the flexible seal 6 is now protected.

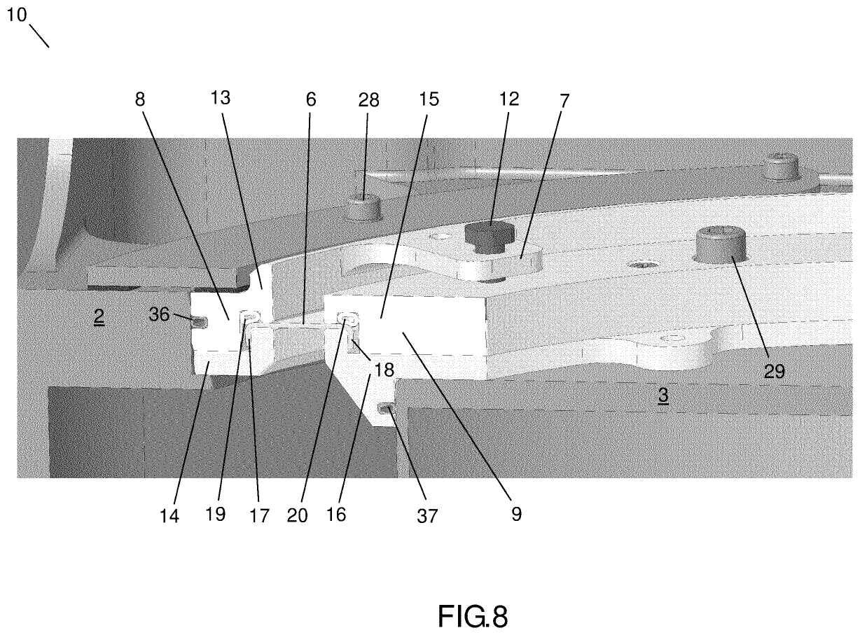

In a second step S2) one among the first assembly 2 and the second assembly 3 is removed. EMC gaskets (cf. gaskets 36 and 37, FIG. 8) may also be removed. Practically the assembly that is removed may be the assembly to which the bridge 7 is not attached.

In a third step S3) the removed assembly is replaced by a new assembly, or the removed assembly is subjected to maintenance, before reattaching it to the flexible seal 6.

In a fourth step S4) the bridge 7 is disengaged or loosened, and the system may return to the operation state.

Another method, which could be implemented in order to completely remove and do maintenance on the flexible seal or to replace it or could provide easier access to at least one of the assemblies as a result of completely removing the flexible seal comprises the following steps:
S1′) rigidly holding the bridge 7 on both sides of the flexible seal 6 which extends between the first assembly 2 and the second assembly 3;
S2′) removing together the bridge 7 and the flexible seal 6;
at least one of the steps of:
   S3a′) replacing the flexible seal 6 by a new one or upkeeping the flexible seal 6, and attaching it to the bridge 7;
   S3b′) replacing or upkeeping one among the first assembly 2 and the second assembly 3; and comprising steps:
S4′) attaching the flexible seal 6 to the first assembly 2 and second assembly 3;
S5′) disengaging or loosening the bridge 7 so as to leave the flexible seal 6 between the first assembly 2 and the second assembly 3.

As described above, step S1′ comprises rigidly holding the bridge 7 on both sides of the flexible seal 6 which extends between the first assembly 2 and the second assembly 3. Because the seal is attached to the first assembly 2 and the second assembly 3 and the bridge is attached to both sides of the flexible seal 6, this means that in step S1′) of the maintenance configuration the bridge 7 holds together the flexible seal 6 and at least one among the first assembly 2 and the second assembly 3. In step S2′) the flexible seal is removed, so it will be clear that it is not required that in all steps of the maintenance configuration the bridge 7 holds together the flexible seal 6 and at least one among the first assembly 2 and the second assembly 3, but only in at least part of the maintenance configuration.

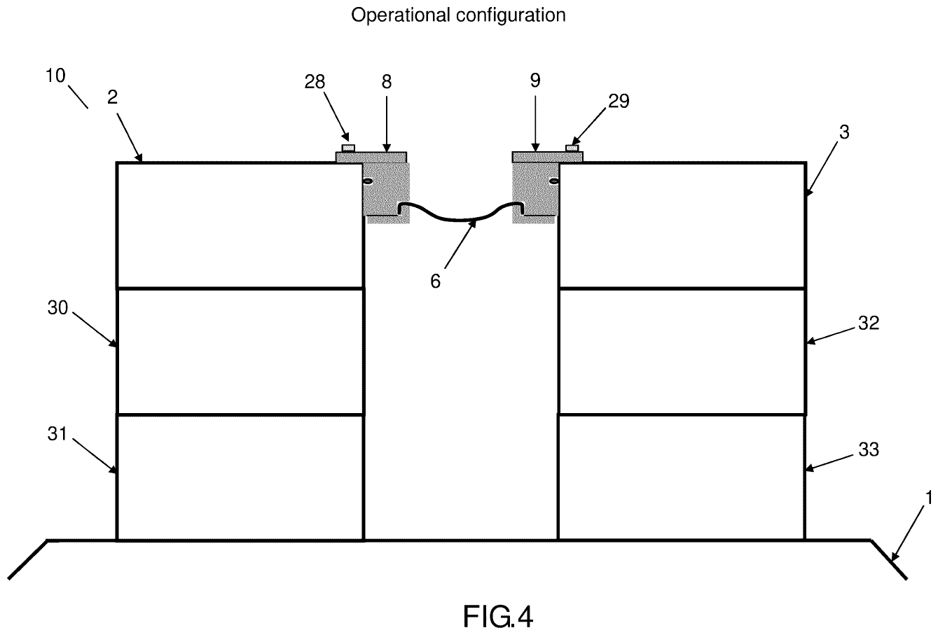

FIGS. 4, 5 and 6 illustrate another embodiment of the invention.

The electronic equipment 10 comprises at least one among a first support 8 and a second support 9 which are respectively releasably attached to the first assembly 2 and second assembly 3. They are preferably made of a conductive material such as metal. In an embodiment, the electronic equipment 10 comprises a single support (at the side of that assembly that is to be removed for maintenance), although it is preferable to provide one support for each assembly, so as to freely intervene on both assemblies, i.e. replacing one of the assemblies, or doing a maintenance operation on one of the assemblies.

In the operational configuration of FIG. 4, which is defined by an absence of transfer of forces between both assemblies via the electromagnetic shield system, the first support 8 is attached to the first assembly 2 by means of a first fastener 28, and the second support 9 is attached to the second assembly 3 by means of a second fastener 29. For example, the fasteners may be threaded fasteners, such as screws, nuts and bolts. The supports also hold the flexible seal 6, for example by pinching it.

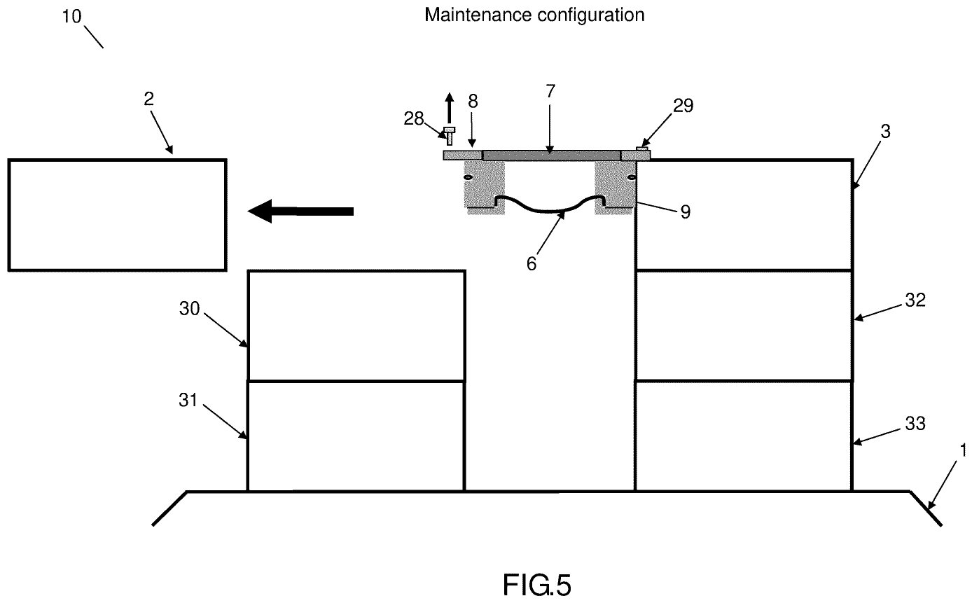

In the maintenance configuration, which is illustrated by FIG. 5, the rigid bridge 7 is installed, and the first fastener 28 is removed by an operator, which enables a removal of the first assembly 2 without tearing or breaking the flexible seal 6. Thanks to the invention, it could be envisioned to add flexible electronics on the flexible seal for instance for the purpose of exchanging information between the first and second assemblies 2,3, or e.g. gathering information about the seal itself (as digital twin).

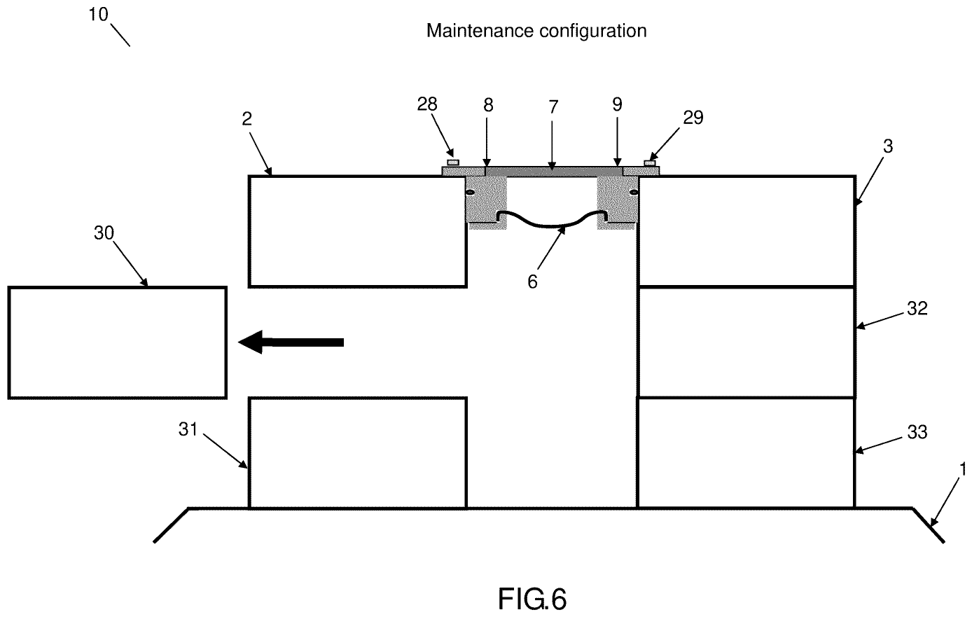

FIG. 6 illustrates another case, wherein a third assembly 30 has to be replaced or repaired during a second maintenance operation. In the operational configuration (FIG. 4), the first support 8 is attached to the first assembly 2 by means of a first fastener 28, and the second support 9 is attached to the second assembly 3 by means of a second fastener 29. The flexible seal 6 is held by the supports so as to avoid any electromagnetic leakage out of the electronic equipment 10 and/or any external electromagnetic attack into the electronic equipment 10. Moreover, there is no transfer of forces between both assemblies in the operational configuration via the electromagnetic shield system.

In the second maintenance configuration, as illustrated by FIG. 6, the rigid bridge 7 is attached to the first support 8 and to the second support 9, so as to enable a transfer of forces between the first assembly 2 and the second assembly 3, and to safeguard the flexible seal. Thanks to the rigid connection, the third assembly 30 may be removed from the electronic equipment for its maintenance, without affecting the mechanical configuration of the flexible seal between the first assembly 2 and the second assembly 3.

In the embodiment of FIG. 6, the first support 8 and second support 9 are optional and if not provided, the rigid bridge 7 may be directly be attached to the first assembly 2 and the second assembly 3. Thanks to the rigid connection between the bridge 7, the first assembly 2 and the second assembly 3, the third assembly 30 may be removed from the electronic equipment for its maintenance, without affecting the mechanical configuration of the flexible seal between the first assembly 2 and the second assembly 3.

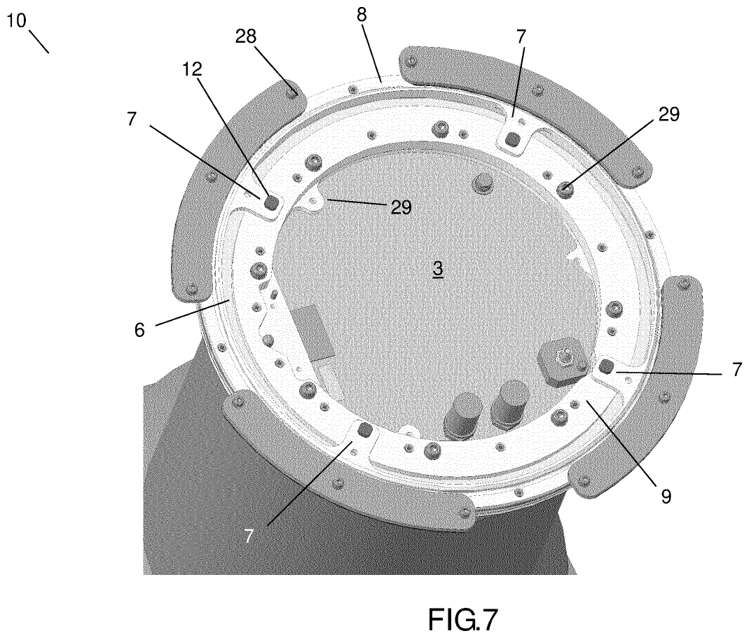

FIGS. 7 and 8 illustrate detailed views of a rotating radar. The second assembly 3 is the rotating part 3 of a rotating joint. It comprises several components which are dedicated to specific functions such as power, control, cooling of the antenna (input and output interfaces for the cooling liquid), etc. The first assembly 2 is the rotating antenna system of the radar (cf. FIG. 8).

The flexible seal 6 extends between the first support 8 and the second support 9 in a tight or preferably in a loose hanging manner. In a preferred embodiment, the first support 8 and the second support 9 are made of two superimposed sub-parts (13, 14, 15, 16), such that the flexible seal 6 is clamped between the superimposed sub-parts (13, 14, 15, 16). The superimposition of two sub-parts may be done through a shoulder in each sub parts, and a gap (17, 18) for receiving the extremities of the flexible seal 6. If the flexible seal is not elastic in its thickness dimension, a recess may be provided in the gap, in order to arrange an elastic element such as a gasket (19, 20). The elastic element (19, 20) presses the flexible seal 6 in the gap (17, 18). If the flexible seal is elastic in its thickness dimension, it may not be necessary to arrange an elastic element.

The superimposed sub-parts may be disengaged, so as to change the flexible seal 6 or the elastic elements (19, 20). Alternatively, the whole combination of supports (8, 9), seal (6), and bridge (7) may be disengaged and replaced.

Besides, elastic elements 36, such as gaskets, may also be provided at the interface between the first assembly 2 and the first support 8, and elastic elements 37, such as gaskets, may be provided at the interface between the second assembly 3 and the second support 9.

The elastic elements guarantee a good contact between the flexible seal and the supports, and also a good contact between the supports and the assemblies, thereby increasing the electromagnetic shielding. The elastic elements may be made of rubber or any suitable material that provides conductive properties, for example an elastic element with a conductive coating.

The aforementioned method can be adapted with the first support and second support: step S1) comprises using at least one among a first support (8) and a second support (9) being respectively releasably attached to the first (2) and second (3) assemblies, wherein the first support (8) and/or second support (9) hold(s) the flexible seal (6),

And step S3) comprises attaching the replaced or upkept assembly to the first support (8) and/or second support (9).

In another embodiment with the first support and second support step S1′) of the aforementioned method comprises using at least one among a first support (8) and a second support (9) being respectively releasably attached to the first (2) and second (3) assemblies, wherein the first support (8) and/or second support (9) hold(s) the flexible seal (6),
Step S2′) comprises removing the first support (8) and/or second support (9);
Optional Step S3a′) comprises attaching the flexible seal (6) to the first support (8) and/or second support (9);
   And step S4′) comprises attaching the first support (8) and/or second support (9) together with the flexible seal (6) to the first assembly 2 and/or second assembly 3.

In a preferred embodiment, the electronic equipment 10 may comprise a plurality of bridges 7, which are preferably evenly distributed along the flexible seal 6. This increases the efficiency of the transfer of forces between the first support 8 and second support 9 and thereby the first assembly 2 and the second assembly 3. For example, there may be four bridges, as illustrated in FIG. 7. The more bridges there are, the more secure the transfer of forces is in the maintenance configuration. However, it also increases the complexity of the maintenance operation, since attaching more bridges takes more time for the operator. Thus, a compromise between rigidity and time can be done during the design of the equipment. The plurality of bridges may also be part of one assembly rather that single bridge elements to ease the maintenance operation.

Advantageously, the bridge 7 is a protrusion of one among the first or second supports, as illustrated by FIG. 8. In the maintenance configuration, a fastener 12 secures the connection between the bridge 7 and the second support 9 and thereby the second assembly 3 (or inversely if the bridge 7 is a protrusion of the second support 9). In case the bridge 7 is a protrusion, the bridge should be dimensioned in such a way that there is no contact between the bridge 7 and the other assembly (for example with the second support 9 in FIG. 8) in the operational configuration. For that, the protruded assembly is raised with regards to the non-protruded assembly. Alternatively, the bridge may be raised itself with regards to the supports.

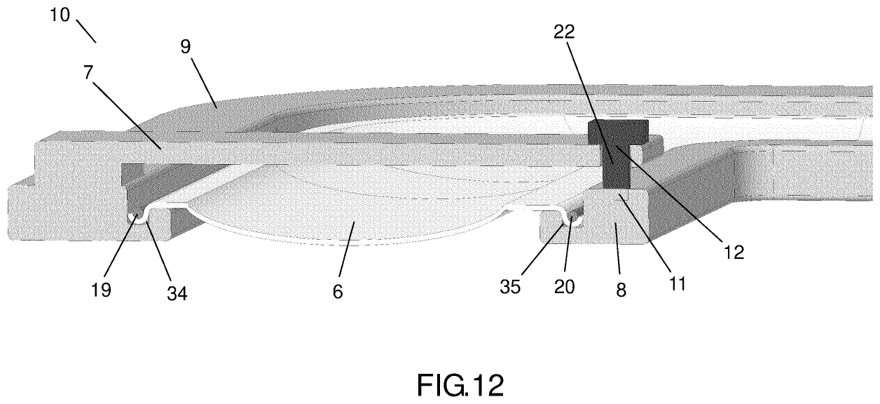

Similarly, the bridge 7 could be a protrusion of one among the first or second assemblies as is illustrated in FIG. 12.

In another embodiment, the bridge 7 is a separate element which is connectable to the first support 8 and/or to the second support 9, or alternatively to the first assembly and/or to the second assembly. Thus, the bridge can be completely removed in operational configuration, and it has to be attached to both supports or to the seal and thereby the assemblies for the maintenance configuration.

The fastener 28 secures the contact between the first assembly 2 and the first support 8, and the fastener 29 secures the contact between the second assembly 3 and the second support 9. For example, the fasteners 28, 29 may be bolts. After having locked the bridge 7 between the first support 8 and the second support 9, the fastener 28 may be disengaged from the first assembly 2, and/or the fastener 29 may be disengaged from the second assembly 3. Once the first or second assembly has been repaired or exchanged, the corresponding fastener is re-engaged so as to secure the connection between the assembly and the support. Thereafter the bridge 7 may be loosened and/or disengaged.

Thus, the invented system is particularly well adapted for maintenance or repair of the components of a rotating radar and/or the seal.

According to an embodiment of the invention (FIG. 12), the bridge 7 comprises a through hole 22 and the first 8 and/or second 9 supports comprises a tapped hole 11. A threaded fastener 12 is engaged in the through hole 22 and in the tapped hole 11 so as to secure the maintenance configuration. The threaded fastener 12 is then disengaged or loosened for the operational configuration. It can be noted that it may not be necessary to remove the threaded fastener 12. The cross section of the through hole 22 may be larger than the one of the threaded fastener 12, hence there is no transfer of forces when the fastener is not tightened yet remains present. In the maintenance configuration, the fastener is completely tightened so as to provide the structural rigidity.

Similarly, the bridge may comprise a through hole and one among the first or second assemblies may comprise a tapped hole, and a threaded fastener which can be engaged in the through hole and in the tapped hole.

According to another embodiment, the first support 8 and/or the second support 9 comprises a through hole and the bridge 7 comprises a tapped hole. A threaded fastener 12 is engaged in the through hole 22 and in the tapped hole 11 so as to secure the maintenance configuration. The threaded fastener 12 is then disengaged for the operational configuration.

Similarly, one among the first or second assemblies may comprise a through hole and the bridge may comprise a tapped hole, and a threaded fastener which can be engaged in the through hole and in the tapped hole.

FIG. 12 illustrates a cross-sectional view of the engagement of the threaded fastener 12 in the through hole 22 and in the tapped hole 11.

Advantageously, the cross section of the through hole 22 is larger than the cross section of the threaded fastener 12. This provides the above described advantage that the fastener 12 does not need to be removed but may remain present in the operation configuration as long as the fastener 12 is not tightened in the operational configuration. As a consequence, the supports may be used to provide a connection between two ill-defined components in terms of geometric dimensioning. The bridge between both supports may house sufficient structural elasticity to make the ill-defined connection while at the same time have sufficient structural rigidity to guarantee an uncompromised seal. Therefore, the dimensioning constraints between the first assembly and the second assembly are released.

Besides, in addition to EMC/EMI shielding, the invented equipment also works as a way of not transferring vibration or structure-borne noise between the supports.

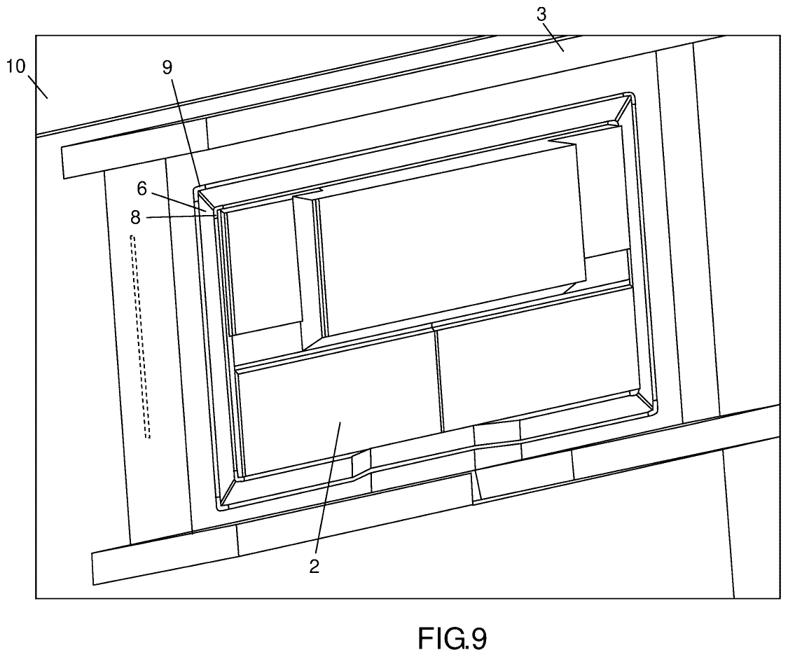

FIGS. 9-12 illustrate another embodiment of the invention for a mast configuration.

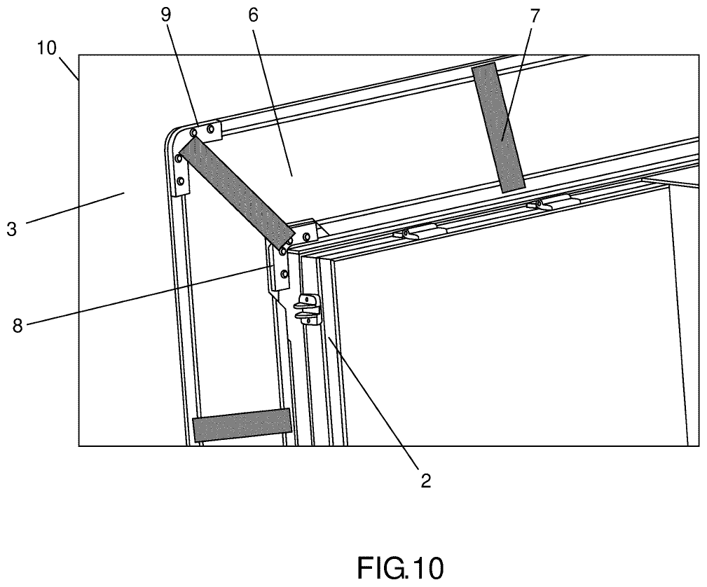

FIG. 9 is a perspective view of a mast antenna, seen from the inside of the mast. In this case, the second assembly 3 is the mast and the first assembly 2 is the antenna system, which includes the support of the antenna and the radiating elements. A flexible seal 6 is arranged between the antenna and the mast, so as to avoid any electromagnetic leakage out of the mast, or electromagnetic interference into the mast. The bridge 7 is held by a first support 8 and by a second support 9, as it can be seen more in details in FIG. 10.

If the antenna needs to be repaired, the operator attaches the rigid bridge 7 to the first support 8 and to the second support 9 or locks the bridge 7 thereto. In the preferred embodiment there is a plurality of bridges. Then, the operator disengages the antenna 2 from the first support 8. Since there is a transfer of forces between the supports 8 and 9, the flexible seal 6 is neither torn nor even displaced. Thus, there is no need to measure or requalify the effectiveness of the electromagnetic seal, after the antenna has been reinstalled. Alternatively, after attaching the rigid bridge 7, the second support 9 may be disengaged from the mast 3 after which the complete antenna system including the seal can be removed for maintenance.

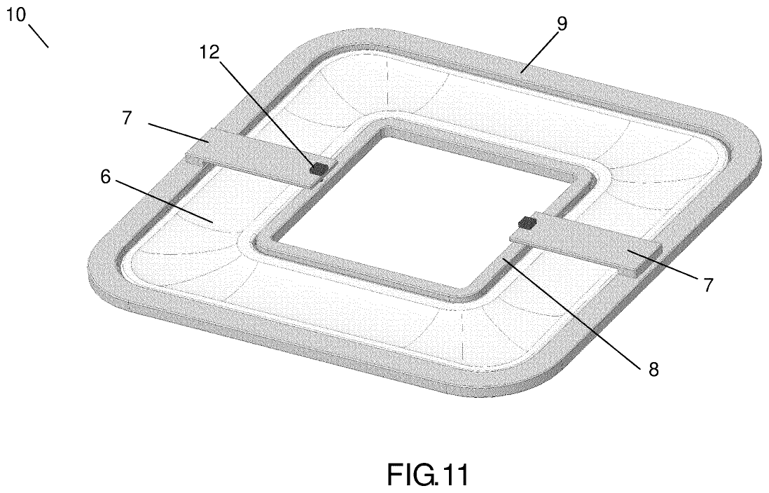

FIGS. 11 and 12 illustrate other embodiments of the mast configuration of the invention. The first support 8 is arranged on the entire circumference of the antenna (not visible in the figures), and the second support 9 is attached to the mast (not visible in the figures). Besides, the equipment comprises two bridges 7. In this embodiment the bridges 7 are an integral part of the second support 9 and are releasably attachable to first support 8. In FIG. 12, a first recess 34 is provided in order to arrange a first elastic element 19, and a second recess 35 is provided in order to arrange a second elastic element 20. The elastic elements may be gaskets. The first elastic element 19 presses the flexible seal 6 in the first recess 34 and the second elastic element 20 presses the flexible seal 6 in the second recess 35.

The first support 8 and the second support 9 may have any suitable shape, in particular in accordance with the space to be spanned and/or object to be sealed. For example, the supports may be substantially ring-shaped as shown in the application of the rotating radar or square shaped as shown in the mast configuration. However, different geometries may be used. Indeed, the two-support structure in itself may provide sufficient design freedom to connect to the to-be-shielded hardware components as well as the bridge connection. The crossover between distinctively different geometries can then be provided by a flexible seal spanning between both supports and/or assemblies.

Optional embodiments of the invention are set out in the following non-limitative first set of clauses:
1) Electronic equipment (10) with an electromagnetic shield system, comprising:
   a first assembly (2) and a second assembly (3), the first assembly (2) and the second assembly (3) being connected in such a manner that there is no direct transfer of forces between them in an operational configuration of the electronic equipment (10);
   a flexible seal (6) configured for providing an electromagnetic shield between the first (2) and second (3) assemblies,
   the electronic equipment (10) further comprising at least one rigid bridge (7) for rigidly holding together the flexible seal (6) and at least one among the first assembly (2) and the second assembly (3), or for rigidly holding the flexible seal (6), so as to intervene on said electronic equipment (10) in a maintenance configuration of the electronic equipment (10).
2) Electronic equipment according to clause 1, further comprising a base (1), the first assembly (2) and the second assembly (3) being directly or indirectly connected to the base (1), the connection of the first assembly (2) to the base (1), and the connection of the second assembly (3) to the base (1) being independent one to each other in the operational configuration of the electronic equipment (10).
3) Electronic equipment according to any of the preceding clauses, wherein the flexible seal (6) comprises an electrically conductive fabric. 4) Electronic equipment according to any of the preceding clauses, comprising a plurality of bridges (7).
5) Electronic equipment according to any of the preceding clauses, comprising at least one among a first support (8) and a second support (9) being respectively releasably attached to the first (2) and second (3) assemblies, the first support (8) and/or the second support (9) being configured for holding the flexible seal (6).
6) Electronic equipment according to clause 5, wherein the bridge (7) is a protrusion of one among the first (8) or second (9) supports.
7) Electronic equipment according to clause 5, wherein the bridge (7) is a separate element which is connectable to the first support (8) and/or to the second support (9).
8) Electronic equipment according to any of clauses 5 to 7, wherein the bridge (7) comprises a through hole (22) and one among the first (8) or second (9) supports comprises a tapped hole (11), and a threaded fastener (12) which can be engaged in the through hole (22) and in the tapped hole (11).
9) Electronic equipment according to any of clauses 5 to 7, wherein one among the first (8) or second (9) supports comprises a through hole and the bridge (7) comprises a tapped hole, and a threaded fastener (12) which can be engaged in the through hole and in the tapped hole.
10) Electronic equipment according to any of clauses 1 to 4, wherein the bridge (7) is a protrusion of one among the first (2) or second (3) assemblies.
11) Electronic equipment according to any of clauses 1 to 4, wherein the bridge (7) is a separate element which is connectable to the first assembly (2) and/or to the second assembly (3).
12) Electronic equipment according to any of clauses 1 to 4, 10 or 11, wherein the bridge (7) comprises a through hole (22) and one among the first (2) or second (3) assemblies comprises a tapped hole (11), and a threaded fastener (12) which can be engaged in the through hole (22) and in the tapped hole (11).
13) Electronic equipment according to any of clauses 1 to 4, 10 or 11, wherein one among the first (2) or second (3) assemblies comprises a through hole and the bridge (7) comprises a tapped hole, and a threaded fastener (12) which can be engaged in the through hole and in the tapped hole.
14) Electronic equipment according to any of clauses 8, 9, 12 or 13, wherein the cross section of the through hole (22) is larger than the cross section of the threaded fastener (12).
15) Electronic equipment according to any of clauses 5 to 9 or 14, wherein each of the first (8) and second (9) supports is made of two superimposed sub-parts (13, 14, 15, 16), such that the flexible seal (6) is clamped between the superimposed sub-parts (13, 14, 15, 16).
16) Electronic equipment according to any of the preceding clauses, wherein the first (2) and second (3) assemblies are mobile one to each other according to a same degree of freedom, the movement of the first (2) and second (3) assemblies being coordinated in the operational configuration of the electronic equipment (10).
17) Electronic equipment according to clause 16, wherein the first (2) and second (3) assemblies are mobile one to each other, each according to a pivot link (4, 5).
18) Electronic equipment according to clause 17, wherein the first assembly (2) is a rotating antenna system, the second assembly (3) is a rotating part of a rotary joint.
19) Electronic equipment according to any of clauses 1 to 15, wherein the second assembly (3) is a mast structure, and the first assembly (2) is an antenna system which is integrated in the mast structure.
20) Method for replacing or performing maintenance on the electronic equipment according to any of the preceding clauses, comprising the following steps:
   S1) rigidly holding together, via the bridge (7), the flexible seal (6) and at least one among the first assembly (2) and the second assembly (3);
   S2) removing one among the first assembly (2) and the second assembly (3);
   S3) replacing the removed assembly by a new assembly or upkeeping the removed assembly, and attaching it to the flexible seal (6);
   S4) disengaging or loosening the bridge (7).
   21) Method according to clause 20, wherein step S1) comprises using at least one among a first support (8) and a second support (9) being respectively releasably attached to the first (2) and second (3) assemblies, wherein the first support (8) and/or second support (9) hold(s) the flexible seal (6), and step S3) comprises attaching the replaced or upkept assembly to the first support (8) and/or second support (9).
22) Method for replacing or performing maintenance on the electronic equipment according to any clauses 1 to 19, comprising the following steps:
   S1′) rigidly holding the bridge (7) on both sides of the flexible seal (6) which extends between the first assembly (2) and the second assembly (3);
   S2′) removing together the bridge (7) and the flexible seal (6);
   at least one of the steps of:
      S3a') replacing the flexible seal (6) by a new one or upkeeping the flexible seal (6), and attaching it to the bridge (7);
      S3b') replacing or upkeeping one among the first assembly (2) and the second assembly (3);
   and comprising steps:
   S4′) attaching the flexible seal (6) to the first (2) and second assembly (3);
   S5′) disengaging or loosening the bridge (7) so as to leave the flexible seal (6) between the first assembly (2) and the second assembly (3).
23) Method according to clause 22, wherein step S1′) comprises using at least one among a first support (8) and a second support (9) being respectively releasably attached to the first (2) and second (3) assemblies, wherein the first support (8) and/or second support (9) hold(s) the flexible seal (6),
   Step S2′) comprises removing the first support (8) and/or second support (9);
   Step S3a′) comprises attaching the flexible seal (6) to the first support (8) and/or second support (9);
   And step S4′) comprises attaching the first support (8) and/or second support (9) together with the flexible seal (6) to the first (2) and/or second assembly (3).

1.-37. (canceled)

38. An electromagnetic shield system, comprising:
a flexible seal configured for providing an electromagnetic shield between assemblies of an electronic equipment in such a manner that there is no direct transfer of forces between the assemblies in an operational configuration of the electronic equipment via the electromagnetic shield system; and
at least one rigid bridge for rigidly holding together the flexible seal and at least one of the two assemblies, or for rigidly holding the flexible seal.

39. The electromagnetic shield system according to claim 38, wherein the flexible seal comprises an electrically conductive fabric.

40. The electromagnetic shield system according to claim 38, wherein the electromagnetic shield system comprises a plurality of bridges.

41. The electromagnetic shield system according to claim 38, wherein the electromagnetic shield system comprises at least one among a first support and a second support being respectively releasably attachable to the first and second assemblies, the first support and/or the second support being configured for holding the flexible seal.

42. The electromagnetic shield system according to claim 41, wherein each of the first and second supports is made of two superimposed sub-parts, such that the flexible seal is clamped between the superimposed sub-parts.

43. The electromagnetic shield system according to claim 41, wherein the bridge is a protrusion of one among the first or second supports, or wherein the bridge is a separate element which is connectable to the first support and/or to the second support.

44. The electromagnetic shield system according to claim 41, wherein the bridge comprises a through hole and one among the first or second supports comprises a tapped hole, and a threaded fastener which can be engaged in the through hole and in the tapped hole, or wherein one among the first or second supports comprises a through hole and the bridge comprises a tapped hole, and a threaded fastener which can be engaged in the through hole and in the tapped hole.

45. The electromagnetic shield system according to claim 38, wherein the bridge is a protrusion of one among the first or second assemblies, or wherein the bridge is a separate element which is connectable to the first assembly and/or to the second assembly.

46. The electromagnetic shield system according to claim 38, wherein the bridge comprises a through hole and one among the first or second assemblies comprises a tapped hole, and a threaded fastener which can be engaged in the through hole and in the tapped hole, or wherein one among the first or second assemblies comprises a through hole and the bridge comprises a tapped hole, and a threaded fastener which can be engaged in the through hole and in the tapped hole.

47. The electromagnetic shield system according to claim 44, wherein the cross section of the through hole is larger than the cross section of the threaded fastener.

48. An electronic equipment with an electromagnetic shield system, the electronic equipment comprising:
a first assembly and a second assembly, the first assembly and the second assembly being connected in such a manner that there is no direct transfer of forces between them in an operational configuration of the electronic equipment via the electromagnetic shield system;
wherein the electromagnetic shield system is the electromagnetic shield system according to claim 38.

49. The electronic equipment according to claim 48, further comprising a base, the first assembly and the second assembly being directly or indirectly connected to the base, the connection of the first assembly to the base, and the connection of the second assembly to the base being independent one to each other in the operational configuration of the electronic equipment.

50. The electronic equipment according to claim 48, wherein the first and second assemblies are mobile one to each other according to a same degree of freedom, the movement of the first and second assemblies being coordinated in the operational configuration of the electronic equipment.

51. The electronic equipment according to claim 50, wherein the first and second assemblies are mobile one to each other, each according to a pivot link.

52. The electronic equipment according to claim 48, wherein the first assembly is a rotating antenna system, the second assembly is a rotating part of a rotary joint.

53. The electronic equipment according to claim 48, wherein the second assembly is a mast structure, and the first assembly is an antenna system which is integrated in the mast structure.

54. A method for replacing or performing maintenance on the electronic equipment according to claim 48, comprising the following steps:
S1) rigidly holding together, via the bridge, the flexible seal and at least one among the first assembly and the second assembly;
S2) removing one among the first assembly and the second assembly;
S3) replacing the removed assembly by a new assembly or upkeeping the removed assembly, and attaching it to the flexible seal; and
S4) disengaging or loosening the bridge.

55. The method according to claim 54, wherein step S1) comprises using at least one among a first support and a second support being respectively releasably attached to the first and second assemblies, wherein the first support and/or second support hold(s) the flexible seal, and step S3) comprises attaching the replaced or upkept assembly to the first support and/or second support.

56. The method for replacing or performing maintenance on the electronic equipment according to claim 48, comprising the following steps:
S1′) rigidly holding the bridge on both sides of the flexible seal which extends between the first assembly and the second assembly;
S2′) removing together the bridge and the flexible seal; at least one of the steps of:
S3a′) replacing the flexible seal by a new one or upkeeping the flexible seal, and attaching it to the bridge;
S3b′) replacing or upkeeping one among the first assembly and the second assembly; and comprising steps:
S4′) attaching the flexible seal to the first and second assembly; and
S5′) disengaging or loosening the bridge so as to leave the flexible seal between the first assembly and the second assembly.

57. The method according to claim 56,
wherein step S1′) comprises using at least one among a first support and a second support being respectively releasably attached to the first and second assemblies, wherein the first support and/or second support hold(s) the flexible seal,
wherein step S2′) comprises removing the first support and/or second support;
wherein step S3a′) comprises attaching the flexible seal to the first support and/or second support; and
wherein step S4′) comprises attaching the first support and/or second support together with the flexible seal to the first and/or second assembly.
